(19) United States
(12) Patent Application Publication
(10) Pub. No.: US 2017/0187421 A1
(43) Pub. Date: Jun. 29, 2017

(54) MULTIPHASE ELECTRICITY METER FOR USE IN SMART GRID POWER NETWORKS

(71) Applicant: Phoenix Systems Sp. z o.o., Warszawa (PL)

(72) Inventor: Pawel Pisarczyk, Warszawa (PL)

(73) Assignee: Phoenix Systems Sp. z o.o., Warszawa (PL)

(21) Appl. No.: 14/757,687

(22) Filed: Dec. 23, 2015

(51) Int. Cl. H04B 3/54; G01R 21/133

(52) U.S. Cl. CPC H04B 3/542; G01R 21/133

(57) ABSTRACT

Embodiments of the present invention provide multiphase electricity meters based on a configurable microprocessor and on a real-time operating system for use in Smart Grid power networks. Hereinafter, said system is referred to as a digital electricity measurement system (DEMS). The DEMS may include a single configurable microprocessor to perform functions of measurement and communication. The single configurable microprocessor is connected via a digital interface IF to analog front-end circuits—AFE: for receiving measurement signals, AFE_{M}: for receiving and transmitting information signals by means of a power line AFE_{PLC}, and/or for generating and receiving a radio signal AFE_{Radio}.

### TECHNICAL FIELD

The present invention generally relates to multiphase electricity meters for use in smart grid networks, but not by way of limitation, to a multiphase electricity meter built based upon a single configurable microprocessor and a real-time operating system, hereinafter referred to as digital electricity measurement system (DEMS).

### BACKGROUND OF THE DISCLOSURE

Architecture of an electricity meter with an extended functionality that allows for various applications to be implemented on the electricity meter is first described in U.S. Patent Application No. 2012/0041696. The above-mentioned electricity meter consists of a main processor, which can be a DSP (digital signal processor), a general-purpose processor or a gate array. A number of peripheral devices are connected to the main processor directly or by means of another DSP (so called preprocessor). The basic devices used for performing measurement functions may be a current sensor connected to sigma-delta converters (20 KS/s, 24 bit) and sigma-delta converters (20 KS/s, 24 bit) directly connected to a power line. Other devices that may be used for the communication signal input into the power line are PLC (power line communication) signal emitters based on DSP.

By way of example, other devices connected to the processor via an optional preprocessor may include a detector of power interruptions, a power controlling unit, a high-precision clock, an Analog Front End circuit for radio communication within the band of 400-1.2 GHz, a digital radio for communication within the band of 1.8-2.8 GHz through PS&FSK modulation, an optical port, a magnetic field detector, a contactor, a tamper and an LCD display. The main processor runs under the control of the kernel of an open-source general-purpose operating system (Linux kernel), where on its basis an environment for application development is implemented. The preprocessor is intended to perform complex algorithms such as, for example, determining energy parameters or processing the PLC signal in order to reduce the load of the main processor.

The electricity meter according to the above-described architecture may include at least one sensor for measuring a signal, allowing to specify energy consumption profile of the customer, and a data processor that processes this signal. The processing of the measured signal is also considered in order to determine the type of devices that consume energy. In addition, a database in which the data processor stores load profiles together with types of said load is also described. Architecture of the measurement system, as described in the above-mentioned prior art is based upon a number of processors—a main processor, an optional DSP preprocessor for data processing, a DSP embedded in the PLC signal emitter, and does not allow for the software implementation of PLC due to the parameters of analog-to-digital converters receiving voltage signals from the line, which are insufficient for such communication. Despite the postulated universality, this is a traditional architecture, consisting of many (at least two) processors.

In U.S. Patent Application No. 2014/0167977, an architecture of Smart Grid node, which is based on a universal microprocessor system (SOM) is described. The Smart Grid node may consist of a processor equipped with a memory management unit (MMU), a RAM memory (64 MB) and a Flash memory (128 MB), a PIC microcontroller equipped with a real time clock (RTC), an EPF module for controlling power and an additional PMIC controller for power control. The SOM module is further equipped with the following interfaces: 2xUSB, 1xSPI, 1xSDIO, 5xUART, 3 analog-to-digital converters, 2xI2C, GPIO. The SOM module may include an 80-pin edge connector, used for connecting to Smart Grid devices such as an electricity meter, a disconnector, etc. In a case of the energy meter implementation, a system specifying energy parameters may be connected to the SOM module via UART or GPIO interface. In addition, a PLC modem or a radio modem may also be connected by means of the interfaces and the edge connector. The SOM module runs under the control of a Linux operating system or any other modern operating systems. The above-mentioned prior art is aimed at an SOM module and its use for the construction of Smart Grid devices. In comparison to the present invention, the universality of applications of the counter according to the embodiments of the present invention is achieved by an SOM module. The SOM module is a general-purpose microprocessor system equipped with many interfaces, which are used for connecting peripheral devices, e.g., a PLC modem or a modem for radio communication. In order to facilitate the implementation of various devices, the microprocessor system runs under a general-purpose operating system allowing the creation of various applications. However, it is not possible to modify the functionality of the device (e.g. the scope of measured energy parameters) by changing only the software.

It is an object of the present invention to develop a universal hardware construction of an electricity meter, allowing for support of popular Smart Grid standards for communication via power lines (such as S-FSK, PRIME, G3, IEEE P1901.2) and for radio communication (such as IEEE 802.15.4, IEEE 802.15.4g) only through the use of appropriate software running on a single processor. This single processor, in addition to communication functions, performs also other tasks, in addition to communication function such as, for example, functions for measuring electricity parameters. Communication via power lines will be interchangeably referred to as PLC. Further, The present invention intends to keep a very low production cost while maintaining a high universality and concurrently an ability to run different applications.

### SUMMARY OF THE INVENTION

Embodiments of the present invention provide a multiphase electricity meter based on a configurable microprocessor and on a real-time system, hereinafter referred to as Digital Electricity Measurement System, for use in Smart Grid power networks. The multiphase electricity meter comprises a single configurable microprocessor to perform functions of measurement and communication. The microprocessor is connected, via a digital interface IF, to AFE circuits for obtaining and receiving measurement signals AFE_{M}, for receiving and transmitting information signals by means of a power line AFE_{PLC} and/or for generating and receiving a radio signal AFE_{Radio}.

In a preferred embodiment, the multiphase electricity meter has a subsystem for implementing measurement functions and another subsystem for implementing communication functions. Despite having shared computing and storage resources, these subsystems are separated from each other using hardware protection mechanisms, embedded in a programming model of the configurable microprocessor, and by means of appropriate mechanisms of the real time operating system. This ensures an appropriate level of rigour in term of time for program implementations, especially with regard to guaranteeing operational reliability of the subsystem used for implementing the measurement functions, according to legal requirements to which electricity meters operating in Smart Grid networks are subject.

Preferably, the entire functionality of the multiphase electricity meter according to the embodiments of the present invention, allows for support of popular Smart Grid standards for communication via power lines: such as, for example, S-FSK, PRIME, G3, IEEEP1901.2, and for radio communication: such as, for example, IEEE 802.15.4, IEEE 802.15.4g. This is achieved only through the use of appropriate software running on a single configurable microprocessor, which, in addition to measurement and communication functions, also performs other tasks, such as for example, functions for measuring quality parameters of electricity.

In a preferable embodiment, the configurable microprocessor is connected via a digital interface IF to an analog front-end circuit, AFE_{PLC}, which is used for receiving and transmitting information signals by means of a power line using standard narrowband modulation such as S-FSK, BPSK, and OFDM, which includes an analog-to-digital converter for receiving communication signals and a digital-to-analog converter, for generating such signal. The analog front-end circuit, AFE, is coupled to any number of available phases. It should be understood that the optional front-end circuit AFE_{PLC} for communication via a power line may be simplified so as to only contain some of the above-mentioned converters.

It is further preferable that the configurable microprocessor has an embedded digital interface IF which is connected to an analog front-end circuit, AFE_{Radio}, used for generating and receiving a radio signal carrying information using any standard digital modulation, such as S-FSK, BPSK, OFDM, CDMA.

In particularly preferred embodiments of the invention, the analog front-end circuit, AFE_{M}, which is used for receiving measurement signals, is integrated with the analog front-end circuit, AFE_{PLC}, used for PLC communication by means of power lines.

Alternatively, it is preferred that the multiphase electricity meter does not have any analog front-end circuit, AFE_{Radio}, for radio communication.

In yet another preferred embodiment, the analog front-end circuit, AFE_{M}, which is used for receiving measurement signals, is integrated with the analog front-end circuit, AFE_{PLC}, used for PLC communication by means of power lines.

Preferably, the analog front-end circuit, AFE, for communication by means of power lines, does not contain any converter, and therefore the digital-to-analog and analog-to-digital converters embedded in the configurable microprocessor are configured to transmit and receive signals by means of power lines.

Preferably, the analog front-end circuit, AFE_{PLC}, for communication by means of power lines is equipped only with one digital-to-analog and one analog-to-digital converters, embedded in the configurable microprocessor which is configured to receive an information signal by means of power lines.

Embodiments of the present invention uses a single configurable microprocessor to implement measurement and communication functions. Separation between these subsystems, which implements said functions by means of shared computing and storage resources, is done with the use of hardware protection mechanisms. The hardware protection mechanisms are embedded in programming model of the single configurable microprocessor, and by means of appropriate mechanisms of the real time operating system which ensure an appropriate level of rigour in term of time for program implementations. In particular, this relates to guaranteeing operational reliability of the subsystem used for implementing the measurement functions, according to legal requirements to which electricity meters operating in Smart Grid networks are subject.

Operational tests of the energy meter for Smart Grid networks according to the embodiments of the present invention proved that it allows for obtaining the same or lower costs of hardware components in the production process. This is mainly due to the fact that several dedicated microprocessor circuits, which are used to implement measurement, communication, and control functions, are replaced by one single microprocessor circuit having an appropriate computing power with a cost which is close to the total cost of all the dedicated circuits. The highest savings are achieved at the level of production cost of the measurement system. Single type of hardware construction, produced within a single technological process, is able to support different type of communications used in the Smart Grid networks and also able to implement various measurement algorithms, including algorithms relating to measurement of power quality. With the use of the configurable microprocessor, it is possible to obtain minimal power consumption while maintaining high universality of the solution.

### BRIEF DESCRIPTION OF THE DRAWINGS

The present disclosure is described in conjunction with the appended figures:

FIG. 1 shows a basic diagram of the meter according to the invention;

FIG. 2 shows an example of a constructional solution of the meter with an analog front-end circuit for PLC communication, integrated with an analog front-end circuit for receiving measurement signals and a separated analog front-end circuit for radio communication,

FIG. 3 shows an example of a constructional solution of the meter with an analog front-end circuit for PLC, an analog front-end circuit for receiving measurement signals without any analog front-end circuit for radio communication,

FIG. 4 shows an example of a constructional solution of the meter with an analog front-end circuit for PLC, integrated with an analog front-end circuit for receiving measurement signals without any analog front-end circuit for radio communication,

FIG. 5 shows an example of a constructional solution of the meter in which an analog front-end circuit for PLC is devoid of analog-to-digital and digital-to-analog converters and is connected to the processor through embedded in the processor an analog-to-digital converter, for receiving signals, and through a digital-to-analog converter for emitting communication signals, and

FIG. 6 shows an example of a constructional solution in which an analog front-end circuit for PLC is devoid of analog-to-digital converter and is connected to the processor through an analog-to-digital converter for receiving communication signals and through a digital interface for transmitting communication signals.

In the drawings, the following designations were used:

1—Configurable microprocessor; 2—Computing cores =CPU; 3—Digital interface for connecting analog front-end circuit for radio communication =IF_{Radio}; 4—Digital interface for connecting analog front-end circuit for PLC=IF_{PLC}; 5—Digital interface for connecting analog front-end circuit for receiving measurement signals=IF_{M}; 6—Analog front-end circuit for radio communication=AFE_{Radio}; 7—Analog front-end circuit for PLC communication =AFE_{PLC}; 8—Analog front-end circuit for receiving measurement signals=AFE_{M}; 9—Analog-to-digital converter for connecting a simplified analog front-end circuit for receiving measurement signals; 10—Digital-to-analog converter for connecting a simplified analog front-end circuit for receiving measurement signals; 11—Phase conductors of the power line; 12—Neutral conductor of the power line; 13—Digital interface for connecting analog front-end circuit for PLC, integrated with an analog front-end circuit for receiving measurement signals=IF_{M}+IF_{PLC}; 14—Analog front-end circuit constituting an integrated analog front-end circuit for PLC communication and an analog front-end circuit for receiving measurement signals=AFE_{M}+AFE_{PLC}; 15—Simplified analog front-end circuit for PLC communication without analog-to-digital and digital-to-analog converters=AFE_{PLC w/o DAC w/o ADC}; 16—Simplified analog front-end circuit for PLC without analog-to-digital converter=AFE_{PLC w/o ADC}; 17—Power line.

### DETAILED DESCRIPTION OF THE INVENTION

In a preferred embodiment, a configurable microprocessor 1 is connected via a digital interface 3, 4 or 5 to an analog front-end circuit AFE_{M} 8 for receiving measurement signals. The configurable microprocessor 1 may include sigma-delta analog-to-digital converters 9, one pair for each phase, used for converting analog measurement signals of current and voltage and a sigma-delta analog-to-digital converter 9 used for measuring current in a neutral wire 12.

The configurable microprocessor 1 is further connected via a digital interface to an analog front-end circuit AFE_{PLC} 7, used for receiving and transmitting information signals by means of a power line 17 using a standard narrowband modulation (e.g., S-FSK, BPSK or OFDM). The configurable microprocessor 1 may include an analog-to-digital converter 9 for receiving a communication signal and a digital-to-analog converter 10 for generating such signal. The AFE circuit is coupled to any number of available phases. The AFE circuit for communication via the power line 17 may also be simplified, and therefore, may not include the complete set of converters.

In an alternative embodiment, the AFE circuit for communication by means of the power line 17 is equipped only with the digital-to-analog converter 10, and the information signal is received by means of the analog-to-digital converter 9 embedded in the microprocessor 1 and a variant in which the analog front-end circuit AFE_{PLC} 7 for communication by means of the power line 17 does not include any of the converters, and the signal is transmitted and received by means of the digital-to-analog converter 10 and the analog-to-digital converter 9 embedded in the microprocessor 1. The configurable microprocessor 1 has an embedded digital interface by means of which it is connected to the analog front-end circuit, AFE_{Radio} 6. The AFE_{Radio} 6 is used for generating and receiving a radio signal, in unlicensed frequency bands, carrying information with the use of any digital modulation (e.g., S-FSK, BPSK, OFDM, CDMA).

It should be noted that the configurable microprocessor 1 may be considered as a processor with an expandable and configurable instruction set (programming model adapted to application), e.g., Cadence's Xtensa or EnSilica's eSI-RISC. In the present disclosure, the processor, by means of an expanded instruction set, may implement procedures of convolutional, repetition, redundant coding and N-point fast Fourier transformation (FFT). These procedures may be used both for the needs of communication via power lines 17, radio communication and for the needs of implementation of measurements of energy parameters. Implementation of computationally intensive algorithms by means of dedicated instructions of the configurable processor allows for a significant (by several times) reduction of power consumption compared to a standard processor.

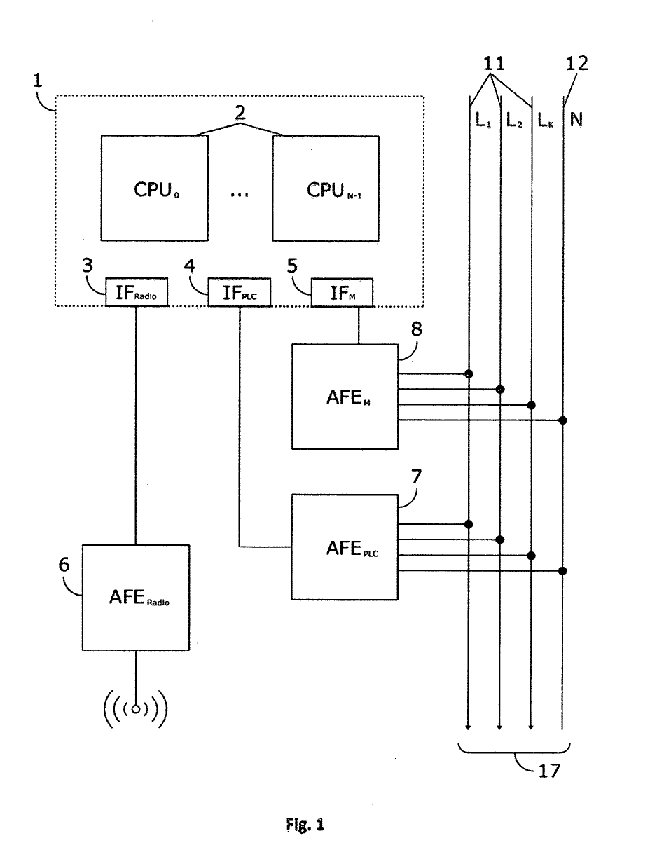

As shown in FIG. 1, the energy meter for Smart Grid networks is equipped with a configurable microprocessor 1 which includes one or more computing cores 2, connected via a digital interface IF_{Radio} 3 to an analog front-end circuit AFE_{Radio} 6, connected via a digital interface TF_{PLC} 4 to an analog front-end circuit for communication AFE_{PLC} 7, connected via a digital interface IF_{M} 5 to an analog front-end circuit AFE_{M} 8, for receiving measurement signals. The analog front-end circuit AFE_{PLC} 7, used for PLC communication, is connected to one or more phase conductors 11 of the power line 17 and to a neutral conductor 12 of the power line 17. The analog front-end circuit AFE_{PLC} 7, used for PLC communication, is responsible for coupling to the power line 17 and for receiving and emitting information signals carried via conductors of the power line 17.

The analog front-end circuit AFE_{M} 8, used for receiving measurement signals, is responsible for receiving measurement signals of voltage between each phase and the neutral conductor 12 and signals of current flowing through the phase conductors 11 of the power line 17 and the neutral conductor 12 of the power line 17. The analog front-end circuit AFE_{Radio} 6, used for radio communication, is responsible for receiving and emitting radio signals in a specific frequency band. Radio signals received by the analog front-end circuit AFE_{Radio} 6 are then transmitted to the configurable microprocessor 1 via a digital interface IF_{Radio} 3, and are emitted based on a digital signal transmitted by the microprocessor 1 by means of the same digital interface IF_{Radio} 3.

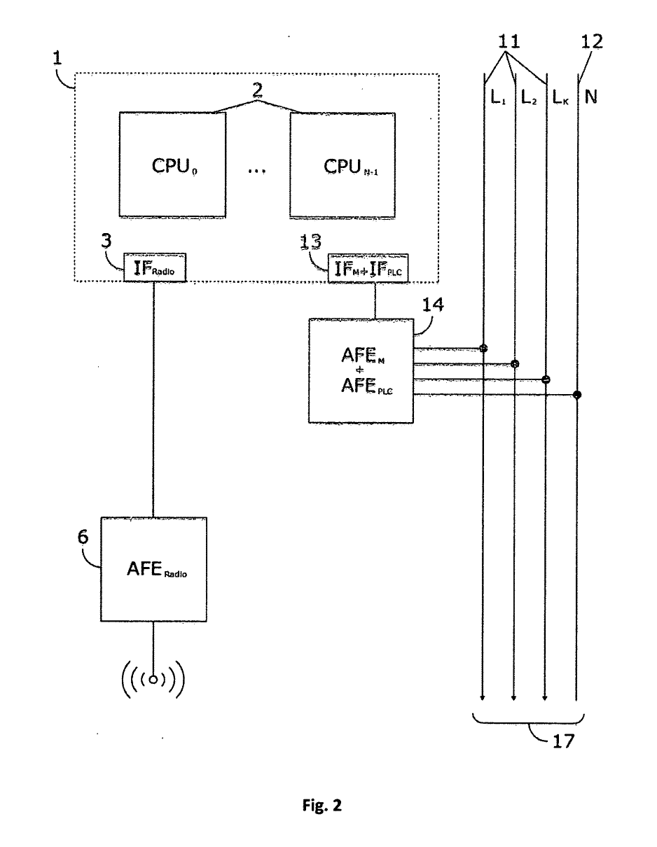

Referring next to FIG. 2, another exemplary embodiment of the multiphase electricity meter is shown. The constructional solution of FIG. 2 differs from the meter of FIG. 1 in that the analog front-end circuits AFE_{PLC} 7 and AFE_{M} 8 are integrated with each other in the form of a single analog front-end circuit AFE_{M}+AFE_{PLC} 14, and digital signals of voltage between each phase and the neutral conductor 12, which are a convolution of the measurement signal and the communication signal, are transmitted to the microprocessor 1. And, digital signals which are to be generated from the power line 17 are transmitted by means of the interface IF_{M}+IF_{PLC} 13 to the analog front-end circuit AFE_{M}+AFE_{PLC} 14. In this embodiment, the analog front-end circuit AFE_{Radio} 6 is connected to the microprocessor 1 by means of the digital interface IF_{Radio} 3.

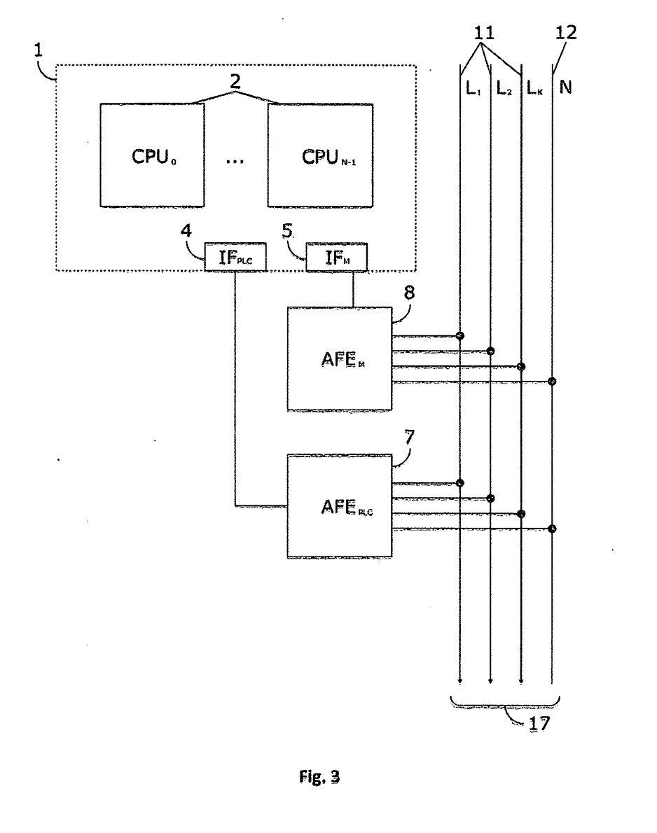

With reference to FIG. 3, another exemplary embodiment of the multiphase electricity meter for Smart Grid Networks is shown. This embodiment differs from the embodiment of the meter shown in FIG. 1 in that the construction is devoid of the analog front-end circuit AFE_{Radio} 6 for radio communication.

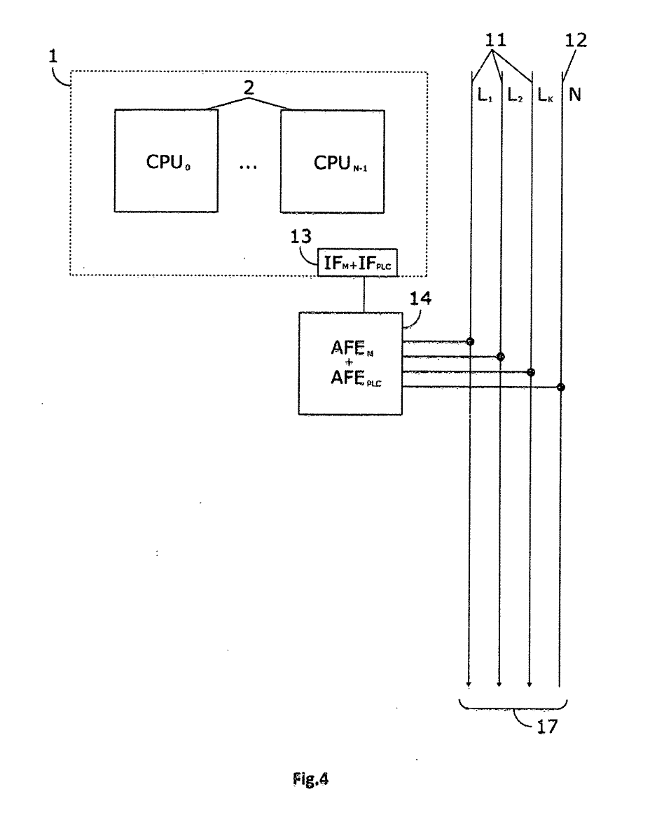

FIG. 4 illustrates an alternative embodiment of the multiphase electricity meter. The embodiment shown in FIG. 4 differs from the embodiment of the meter of FIG. 2 in that the construction is devoid of the analog front-end circuit AFE_{Radio} 6 for radio communication.

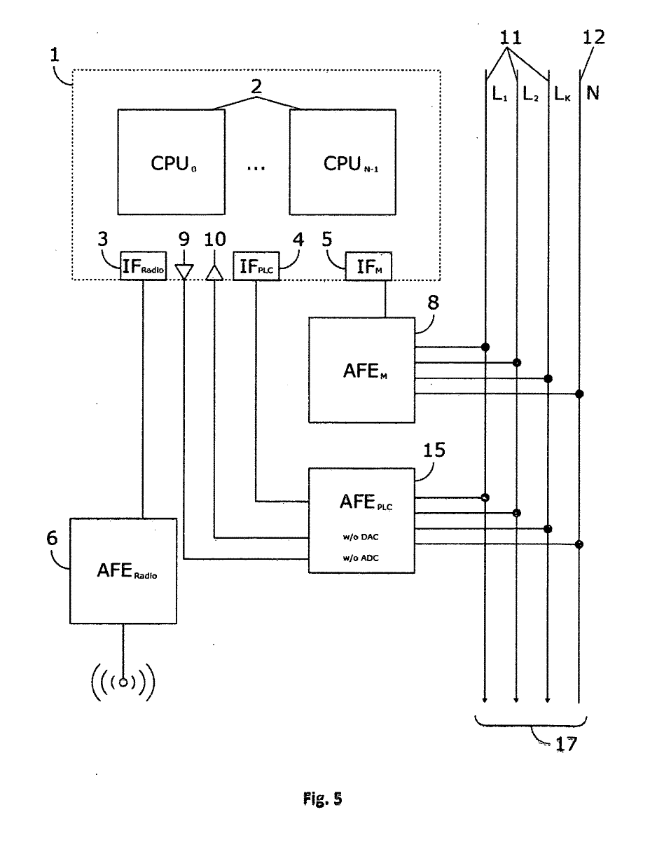

Referring next to FIG. 5, yet another exemplary embodiment of the multiphase electricity meter is shown. The meter shown in FIG. 5 differs from the embodiments of the meters shown in FIGS. 1-4 in that the analog front-end circuit AFE for PLC communication is simplified and is devoid of the analog-to-digital converter 9 and the digital-to-analog converter 10. Simplified analog front-end circuit AFE for PLC without analog-to-digital and digital-to-analog converters is connected to the microprocessor 1 by means of the analog-to-digital converter 9 and the digital-to-analog converter 10 both embedded in the microprocessor 1 and by means of the digital interface IF_{PLC} 4.

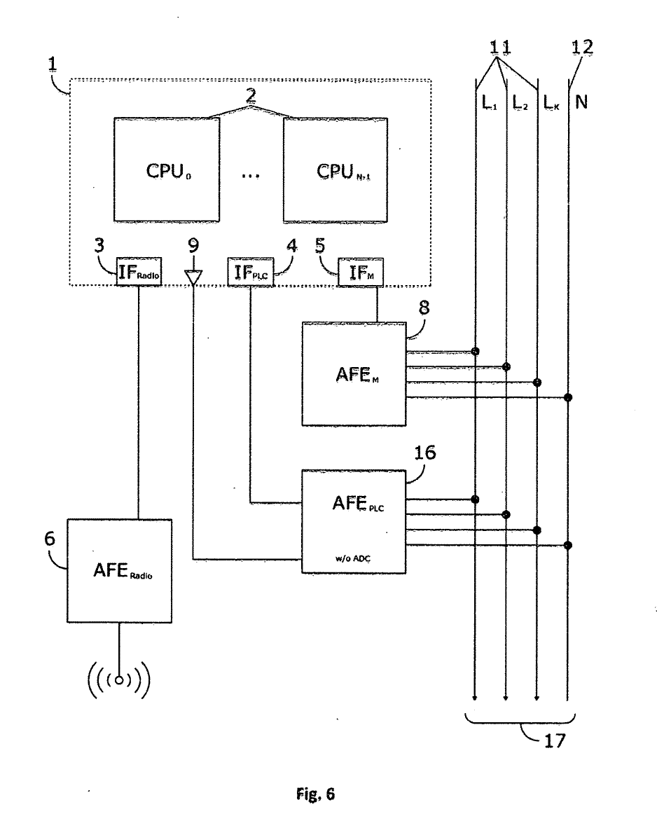

FIG. 6 illustrates an alternative embodiment of the multiphase electricity meter. The embodiment shown in FIG. 6 differs from the embodiment of the meter of FIG. 5 in that the analog front-end circuit AFE for PLC communication is devoid of the analog-to-digital converter. Simplified analog front-end circuit for PLC without the analog-to-digital converter 16 is connected to the microprocessor 1 by means of the analog-to-digital converter 9 embedded in the microprocessor 1 and by means of the digital interface TF_{PLC} 4.

The solutions suggested in the present discloure uses only one single configurable microprocessor 1 which is connected by means of digital interfaces IF to the analog front-end circuits AFE, for PLC, for receiving measurement signals and for radio communication. In addition, it should be emphasized that the essence of sharing a single processor by many different functions is the use of a real-time operating system, which separates software modules and provides them with appropriate computing resources, at the appropriate time.

In the patent application, universal applicability is ensured exclusively by the software and the presence of the single processor. All functions of the device (e.g. measurement, communication) are implemented only by appropriate software operating under a real-time operating system.

1. A multiphase electricity meter based on a configurable microprocessor and on a real-time system, hereinafter referred to as Digital Electricity Measurement System, for use in Smart Grid power networks, the meter comprises a single configurable microprocessor to perform functions of measurement and communication, and the single configurable microprocessor is connected via a digital interface IF to analog front-end circuits, AFE, for receiving measurement signals AFE_{M}, for receiving and transmitting information signals by means of a power line AFE_{PLC} and/or for generating and receiving a radio signal AFE_{Radio} 4.

2. The meter according to claim 1, further comprises a subsystem implementing measurement functions and a subsystem implementing communication functions, and despite these subsystems having shared computing and storage resources, they are separated from each other using hardware protection mechanisms embedded in programming model of the configurable microprocessor and by means of appropriate mechanisms of the real time operating system which ensure an appropriate rigour of time for the execution of programs, especially with regard to guaranteeing operational reliability of the subsystem executing measurement functions, according to legal requirements to which electricity meters operating in Smart Grid networks are subject.

3. The meter according to claim 1, wherein the meter functionality allow for support of popular Smart Grid standards for communication via power lines and for radio communication is implemented only through the use of appropriate software running on the single configurable microprocessor which, in addition to measurement and communication functions, also performs other tasks, including functions for measuring quality parameters of electricity.

4. The meter according to claim 1, wherein the configurable microprocessor is connected via a digital interface IF to an analog front-end circuit, AFE_{PLC}, used to receive and transmit information signals by means of a power line with the use of a narrowband modulation, comprising an analog-to-digital converter for receiving a communication signal and a digital-to-analog converter, used to generate such signal, and the analog front-end circuit, AFE, is coupled to any number of available phases, wherein optionally the AFE_{PLC} circuit for communication via the power line can be simplified and contain only some converters.

5. The meter according to claim 4, wherein the configurable microprocessor has an embedded digital interface IF by means of which it is connected to the analog front-end circuit, AFE_{Radio}, used to generate and to receive a radio signal carrying information with the use of any digital modulation, comprising S-FSK, BPSK, OFDM, or CDMA.

6. The meter according to claim 5, wherein the analog front-end circuit, AFE_{M}, for receiving measurement signals is integrated with the analog the front-end circuit, AFE_{PLC}, for communication by means of power lines—Power Line Communication, PLC.

7. The meter according to claim 5, does not have any analog front-end circuit, AFE_{Radio}, for radio communication.

8. The meter according to claim 4, wherein the analog front-end circuit, AFE_{M}, for receiving measurement signals is integrated with the analog front-end circuit, AFE_{PLC}, for communication by means of power lines—Power Line Communication, PLC.

9. The meter according to claim 5, wherein the analog front-end circuit, AFE, for communication by means of a power line does not contain any converter, and digital-to-analog converters and analog-to-digital converters embedded in the configurable microprocessor are configured to transmit and receive signals by means of the power line.

10. The meter according to claim 5, wherein the analog front-end circuit, AFE, for communication by means of a power line is equipped only with a digital-to-analog converter, and an analog-to-digital converter embedded in the configurable microprocessor is configured to receive an information signal by means of the power line.

11. The meter according to claim 3, wherein the popular Smart Grid standards for communication via power lines comprises S-FSK, PRIME, G3, or IEEEP1901.2.

12. The meter according to claim 3, wherein the popular Smart Grid standards for radio communication comprises IEEE 802.15.4 or IEEE 802.15.4g.

13. The meter according to claim 4, wherein the narrowband modulation comprises S-FSK, BPSK, or OFDM.
